(19) United States
(12) Patent Application Publication
(10) Pub. No.: US 2020/0168442 A1
(43) Pub. Date: May 28, 2020

(54) FOCUS RING HEIGHT ADJUSTING DEVICE AND WAFER ETCHING APPARATUS INCLUDING THE SAME

(71) Applicant: SEMES CO., LTD., Chungcheongnam-do (KR)

(72) Inventors: Byung Kyu Kim, Seoul (KR); Duk Hyun Son, Chungcheongnam-do (KR)

(21) Appl. No.: 16/682,338

(22) Filed: Nov. 13, 2019

(30) Foreign Application Priority Data
Nov. 22, 2018 (KR) 10-2018-0145738

(51) Int. Cl. H01J 37/32

(52) U.S. Cl. CPC H01J 37/32642; H01L 21/67069; H01J 37/32532

(57) ABSTRACT

Provided are a focus ring height adjusting device motor configured to compensate for an inclination of a focus ring using a lift pin vertically operated by a motor and a wafer etching apparatus including the same. The focus ring height adjusting device includes the focus ring, a first lift pin configured to move upward at one side of the focus ring height adjusting device to come into contact with the focus ring, and a second lift pin configured to move upward at the other side of the focus ring height adjusting device to come into contact with the focus ring, wherein the first lift pin and the second lift pin move upward until both of the first lift pin and the second lift pin come into contact with the focus ring to compensate for an inclination of the focus ring.

### CROSS-REFERENCE TO RELATED APPLICATIONS

This application claims priority from Korean Patent Application No. 10-2018-0145738, filed on Nov. 22, 2018, in the Korean Intellectual Property Office, the disclosure of which is incorporated herein by reference in its entirety.

### BACKGROUND

### 1. Field of the Disclosure

The present disclosure relates to a focus ring height adjusting device configured to adjust a height of a focus ring formed at a circumference of a wafer and a wafer etching apparatus including the same.

### 2. Description of the Related Art

Semiconductor elements may be manufactured by forming predetermined patterns on wafers. When the predetermined patterns are formed, various processes such as depositing processes, photolithography processes, etching processes, and the like may be consecutively performed.

### RELATED ART DOCUMENT

### Patent Document

Korean Laid-Open Patent Publication No. 10-2007-0008980 (Publication Date: Jan. 18, 2007)

### SUMMARY

When a wafer seated on an electro-static chuck (ESC) is etched through an etching process, a focus ring may be formed at a circumference of the wafer. The focus ring serves to reduce an etching non-uniformity of the wafer which may occur due to a non-uniform plasma distribution.

However, since the focus ring may be etched when the wafer is etched, a technology for compensating for an etched height of the focus ring by adjusting a height of the focus ring after an etching process is performed on the wafer is required.

The present disclosure is directed to providing a focus ring height adjusting device configured to compensate for a slope of a focus ring using a lift pin vertically operated by a motor, and a wafer etching apparatus including the same.

Objectives of the present disclosure are not limited to the above-described objectives, and other objectives which are not described above will be clearly understood by those skilled in the art from the following description.

According to an aspect of the present disclosure, there is provided a focus ring height adjusting device including a focus ring, a first lift pin configured to move upward at one side of the focus ring height adjusting device to come into contact with the focus ring, and a second lift pin configured to move upward at the other side of the focus ring height adjusting device to come into contact with the focus ring, wherein the first lift pin and the second lift pin move upward until both of the first lift pin and the second lift pin come into contact with the focus ring to compensate for an inclination of the focus ring.

The focus ring, the first lift pin, and the second lift pin may be formed of conductive materials.

The conductive material may be any one of silicon carbide (SiC) and titanium dioxide (TiO₂).

The first lift pin and the second lift pin may be electrically connected, and whether both of the first lift pin and the second lift pin come into contact with the focus ring may be determined on the basis of whether a closed circuit is formed between the focus ring, the first lift pin, and the second lift pin.

The focus ring height adjusting device may further include an electric signal supply provided on a wire electrically connecting the first lift pin to the second lift pin and configured to transmit an electric signal to the first lift pin and the second lift pin, and an electric signal meter provided on the wire and configured to determine whether the electric signal is flowing, wherein the electric signal supply and the electric signal meter may be used to determine whether the closed circuit is formed.

The first lift pin and the second lift pin may continuously move upward at the same speed until it is determined that the closed circuit is formed.

The focus ring height adjusting device may further include a first lift pin controller configured to vertically move the first lift pin and a second lift pin controller configured to vertically move the second lift pin, wherein the first lift pin controller and the second lift pin controller may include stepping motors, and pulses of the stepping motors may be adjusted to control moving distances of the first lift pin and the second lift pin.

According to another aspect of the present disclosure, there is provided a wafer etching apparatus including a housing, a shower head installed in the housing and serving as an upper electrode, a susceptor installed in the housing and serving as a lower electrode, an electro-static chuck (ESC) which is installed on the susceptor and on which a wafer is seated, and a focus ring height adjusting device including a focus ring formed on the susceptor to surround the wafer, a first lift pin configured to move upward at one side of the focus ring height adjusting device to come into contact with the focus ring, and a second lift pin configured to move upward at the other side of the focus ring height adjusting device to come into contact with the focus ring, wherein the focus ring height adjusting device is configured to move the first lift pin and the second lift pin upward until both of the first lift pin and the second lift pin come into contact with the focus ring to compensate for an inclination of the focus ring.

Other specific contents according to the embodiments are included in the detailed descriptions and the accompanying drawings.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a conceptual view illustrating a wafer etching apparatus according to one embodiment;

FIG. 2 is a schematic cross-sectional view illustrating a process chamber included in the wafer etching apparatus according to one embodiment;

FIG. 3 is a conceptual view illustrating a focus ring height adjusting device according to one embodiment of the present disclosure;

FIG. 4 is a conceptual view illustrating a focus ring height adjusting device according to another embodiment of the present disclosure;

FIG. 5 is a conceptual view illustrating a focus ring height adjusting device according to still another embodiment of the present disclosure; and

FIG. 6 is a flow view illustrating a method of compensating for a height of a focus ring using a focus ring height adjusting device according to one embodiment of the present disclosure.

### DETAILED DESCRIPTION OF THE EMBODIMENTS

Hereinafter, exemplary embodiments of the present disclosure will be described in detail with reference to the accompanying drawings. Advantages and features of the present disclosure and methods of achieving the same will be clearly understood with reference to the following embodiments which will be described in detail and the accompanying drawings. However, the present disclosure is not limited to the embodiments to be disclosed below and may be implemented in different various forms. The embodiments are provided in order to fully explain the present disclosure and fully explain the scope of the present disclosure to those skilled in the art. The scope of the present disclosure is only defined by the appended claims. Like reference numerals refer to like elements throughout the specification.

A case in which an element or layer is referred to as being “on” another element or layer includes a case in which the element is directly present on another element or layer and also includes a case in which the element is present on another element or layer with still another element or layer interposed therebetween. However, a case in which an element is referred to as being “directly on” another element includes a case in which still another element or layer is not interposed therebetween.

Spatially relative terms such as “below,” “beneath,” “lower,” “above,” “upper,” and the like may be used to more easily describe a relationship between one element or components and another element or other components as illustrated in the drawings. The spatially relative terms should be understood to have directions as illustrated in the drawings and have other directions when the elements are used or operated. For example, when an upside of an element illustrated in the drawing is turned down, the element which is illustrated to be present on below or beneath another element may be present above another element. Accordingly, the term “below” used as an example including both a downward direction and an upward direction. An element may be arranged in another direction, and thus, the spatially relative terms may be interpreted based on an arrangement direction.

Although first, second, and the like are used to describe various elements, components, and/or sections, the various elements, components, and/or sections are not limited thereto. The terms are only to distinguish one element or component, or sections from another element or component, or sections. Therefore, a first element, a first component, or a first section may also be a second element, a second component, or a second section in the technical spirit of the present disclosure.

The terms used herein are provided to only describe embodiments of the present disclosure and not to limit the present disclosure. Unless the context clearly indicates otherwise in the specification, the singular forms include the plural forms. It will be understood that the terms “comprise” and/or “comprising” used in the specification do not preclude the presence or addition of one or more other components, steps, operations, and/or elements to a component, a step, an operation, and/or an element.

Unless otherwise defined, all terms (including technical and scientific terms) used in the specification can be used as is customarily understood to those skilled in the art to which this disclosure belongs. Also, it will be further understood that terms, such as those defined in generally used dictionaries, will not be interpreted in idealized or overly formal senses unless clearly and expressly defined herein.

Hereinafter, example embodiments of the disclosure will be described in detail with reference to the accompanying drawings. When the embodiments are described with reference to the accompanying drawings, components that are the same or correspond to each other are denoted by the same reference numerals regardless of the figure numbers, and redundant descriptions will be omitted.

A technology for compensating for a height of an etched focus ring by adjusting a height of the focus ring is required as a solution for resolving a problem of productivity reduction caused by etching a focus ring.

In order to improve productivity, the height of the focus ring should be adjusted such that the focus ring is horizontally aligned on an electro-static chuck (ESC). Inclination of the focus ring in one direction may be a cause of asymmetry of plasma, and thus, the productivity of a wafer may also be reduced.

The present disclosure relates to a focus ring height adjusting device configured to compensate for a height of a focus ring using a lift pin vertically operated by a motor. In addition, the present disclosure relates to a wafer etching apparatus including the focus ring height adjusting device. Hereinafter, the present disclosure will be described in detail with reference to the accompanying drawings and the like.

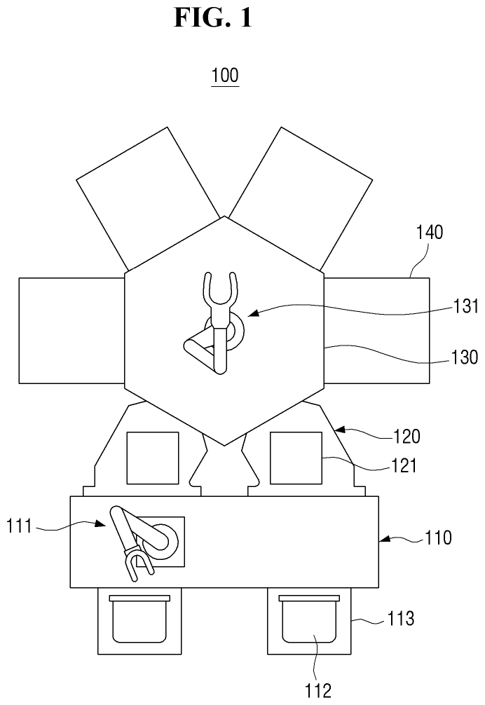

FIG. 1 is a conceptual view illustrating a wafer etching apparatus according to one embodiment.

A wafer etching apparatus 100 performs an etching process on a plurality of wafers. The wafer etching apparatus 100 may be formed as a multi-chamber type wafer process system including a transfer robot (or a handler) and a plurality of wafer processing modules.

Referring to FIG. 1, the wafer etching apparatus 100 may include an index 110, load lock chambers 120, a transfer chamber 130, and process chambers 140.

The index 110 is referred to as an equipment front end module (EFEM) and includes a transfer robot 111 operated at an atmospheric pressure. The transfer robot 111 serves to transfer a wafer between a front opening unified pod (FOUP) 112 and the load lock chamber 120.

Meanwhile, loading ports 113 on which FOUPs 112 are placed are installed in front of the index 110.

The load lock chamber 120 serves as a buffer between input/output ports of the wafer etching apparatus 100. When wafers are loaded on the load lock chamber 120, the wafers in the load lock chamber 120 are transferred to the process chamber 140 by a transfer robot 131 of the transfer chamber 130. Buffer stages 121, on which wafers temporarily stand by, are formed in the load lock chamber 120.

When the transfer robot 131 of the transfer chamber 130 loads or unloads a wafer, a vacuum atmosphere which is (substantially) the same as that of the transfer chamber 130 is formed in the load lock chamber 120, and when an unprocessed wafer is received from the transfer robot 111 of the index 110 or a processed wafer is transferred to the index 110, an atmospheric pressure is generated in the load lock chamber 120. That is, the load lock chamber 120 maintains a pressure by switching between a vacuum state and an atmospheric pressure state so as to prevent an air pressure of the transfer chamber 130 from being changed.

The transfer chamber 130 includes the transfer robot 131 provided to freely rotate. The transfer robot 131 of the transfer chamber 130 transfers an unprocessed wafer to the process chamber 140 from the load lock chamber 120 or transfers a processed wafer to the load lock chamber 120 from the process chamber 140. All sides of the transfer chamber 130 are connected to the plurality of process chambers 140 and the load lock chambers 120.

The process chamber 140 provides a space in which an etching process is performed on a wafer. The process chamber 140 may be formed of alumite of which a surface is coated with a positive oxide film, and an inside of the process chamber 140 may be sealed.

The process chamber 140 may be formed to have a cylindrical shape. However, the present embodiment is not limited thereto. The process chamber 140 may also be formed to have a rectangular hexahedron shape or other shapes.

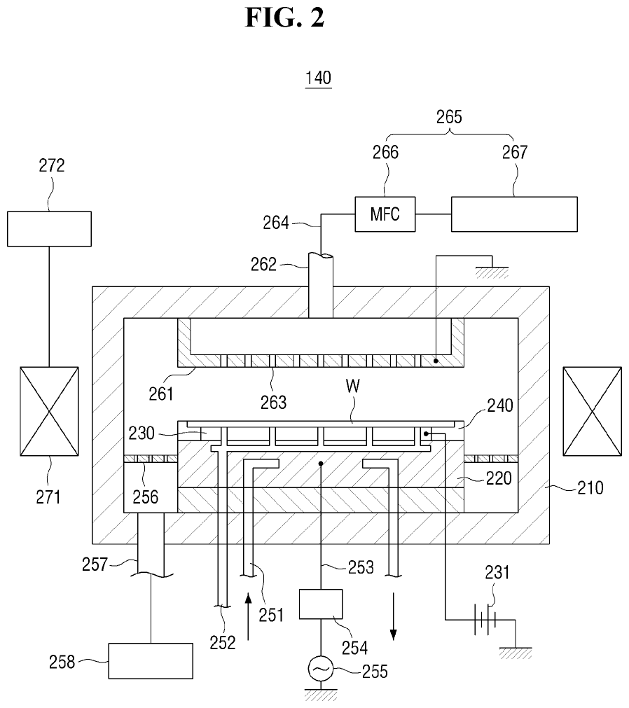

The process chamber 140 may be formed as described below to perform an etching process on a wafer. FIG. 2 is a schematic cross-sectional view illustrating the process chamber included in the wafer etching apparatus according to one embodiment.

Referring to FIG. 2, the process chamber 140 may include a housing 210, a susceptor 220, an ESC 230, and a focus ring 240.

The susceptor 220 serves as a lower electrode and is installed in the housing 210. For example, the susceptor 220 may be formed of alumite on which a positive oxide film is formed.

The ESC 230 is formed on a surface of the susceptor 220 on which a wafer W will be loaded. The ESC 230 may be formed of ceramic as a main material, and a direct current (DC) power source 231 may be connected to an electrode for the ESC.

The focus ring 240 formed to have a ring shape is provided on the susceptor 220 and/or the ESC 230 to surround the wafer W. In the present embodiment, a height of the focus ring 240 may be adjusted by lift pins. A detailed description thereof will be described below.

A heat medium path 251 may be installed in the susceptor 220 to circulate an insulating fluid so as to control a temperature. Since the insulating fluid controlled to have a predetermined temperature circulates in the heat medium path 251, the susceptor 220 may be controlled to have the predetermined temperature.

A gas path 252 may be provided in the susceptor 220 to supply a temperature control gas such as helium gas to a rear surface of the wafer W. The gas path 252 may supply the temperature control gas between the susceptor 220 and the rear surface of the wafer W to facilitate heat exchange between the susceptor 220 and the wafer W. Accordingly, the gas path 252 may improve a precision degree of a semiconductor element manufactured on the wafer W.

A supply wire 253 may be connected to a central portion of the susceptor 220 to supply high frequency power. The supply wire 253 is connected to a radio frequency (RF) power source 255 through a matcher 254. The RF power source 255 may supply the high frequency power.

An exhaust ring 256 formed to have a ring shape may be provided at an outer side of the susceptor 220. Since a plurality of exhaust holes are formed in the exhaust ring 256, a vacuum pump (not shown) of an exhaust system 258 connected to an exhaust port 257 may serve as a vacuum exhaust in the housing 210.

A shower head 261 may be provided above the susceptor 220 to face and be parallel to the susceptor 220. Since the shower head 261 is formed to be grounded, the susceptor 220 and the shower head 261 may be formed to serve as a pair of electrodes (the shower head 261 servers as an upper electrode, and the susceptor 220 serves as a lower electrode).

A gas inlet port 262 and a plurality of gas discharge holes 263 are respectively formed at an upper portion and a lower portion of the shower head 261, and a gas diffusion gap (not shown) may be formed in the shower head 261. The gas inlet port 262 may be connected to one side of a gas supply pipe 264, and a gas supply system 265 may be connected to the other side of the gas supply pipe 264. The gas supply system 265 may include a mass flow controller (MFC) 266 and a reactive gas supply source 267. The MFC 266 is for controlling a gas flow rate, and the reactive gas supply source 267 is for supplying a reactive gas.

When power is applied to each of the susceptor 220 and the shower head 261, a source gas (for example, CF₄ gas which is an etching gas containing fluoride) may be introduced into the housing 210 through the gas inlet port 262 and may be excited into a plasma between the susceptor 220 and the shower head 261. Therefore, radicals and ions forming the plasma may etch the wafer W seated on the ESC 230. Reaction byproducts remaining after the etching process may be discharged to the outside of the housing 210 through the exhaust system 258.

Meanwhile, a magnetic field generator 271 having a ring shape may be disposed around an outer side of the housing 210. The magnetic field generator 271 may be formed in a ring magnet form to generate a magnetic field in a space between the susceptor 220 and the shower head 261. The magnetic field generator 271 may be formed such that an entirety of the magnetic field generator 271 is rotated about the housing 210 at the predetermined rotation speed by a rotating unit 272.

Next, a focus ring height adjusting device configured to adjust a height of a ring focus using a lift pin will be described.

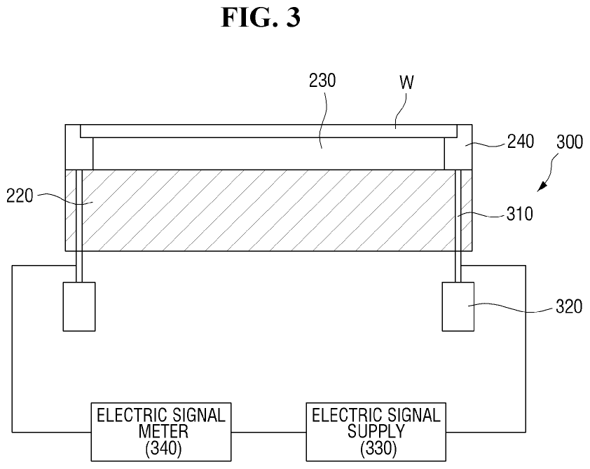

FIG. 3 is a conceptual view illustrating a focus ring height adjusting device according to one embodiment of the present disclosure.

Referring to FIG. 3, a focus ring height adjusting device 300 may include lift pins 310, lift pin controllers 320, an electric signal supply 330, and an electric signal meter 340.

The lift pins 310 are vertically operated by the lift pin controllers 320 and may be provided in the susceptor 220. The lift pins 310 are positioned under the focus ring 240 and may serve to move the focus ring 240 upward.

The plurality of lift pins 310 may be formed under the focus ring 240. Here, the lift pins 310 may be formed at predetermined intervals along a lower portion of the focus ring 240. Since the lift pins 310 are formed as described above, the lift pins 310 may contribute to control of the focus ring 240 to not be inclined in one direction.

The lift pin 310 and the focus ring 240 may be formed of conductive materials. As an example, the lift pin 310 and the focus ring 240 may be formed of silicon carbide (SiC), titanium dioxide (TiO₂), or the like. When the lift pin 310 and the focus ring 240 are formed of silicon carbide, titanium dioxide, or the like, an effect can be obtained that the number of particles generated by etching is minimized.

However, the present embodiment is not limited thereto. When an apparatus configured to remove the particles is provided in the process chamber 140 or the vacuum pump of the exhaust system 258 effectively treats the particles, the lift pin 310 and the focus ring 240 may also be formed of conductive materials other than the silicon carbide and titanium dioxide.

The lift pin controller 320 serves to vertically move the lift pin 310 in the susceptor 220. The lift pin controller 320 may include a motor (for example, a stepping motor) to vertically move the lift pin 310. In a case in which the lift pin controller 320 includes the stepping motor, the lift pin controller 320 may precisely control an amount of change in height of the lift pin 310 by adjusting a pulse of the stepping motor.

The electric signal supply 330 applies an electric signal and may be formed as an apparatus configured to supply power. The electric signal supply 330 may be provided on a wire connecting two different lift pins so that the two different lift pins are electrically connected.

The electric signal meter 340 measures an electric signal to determine whether the electric signal is flowing and may be formed as an apparatus configured to measure a current (or voltage). The electric signal meter 340 is connected to the electric signal supply 330 in series and provided on a wire connecting the two different lift pins like the electric signal supply 330 so that the two different lift pins may be electrically connected.

Although two lift pins 310 may be provided in the present embodiment, three or more lift pins 310 may also be provided. The focus ring height adjusting device 300 may further include a switching element by considering such an aspect. Hereinafter, an example of a case in which four lift pins 310 are provided will be described.

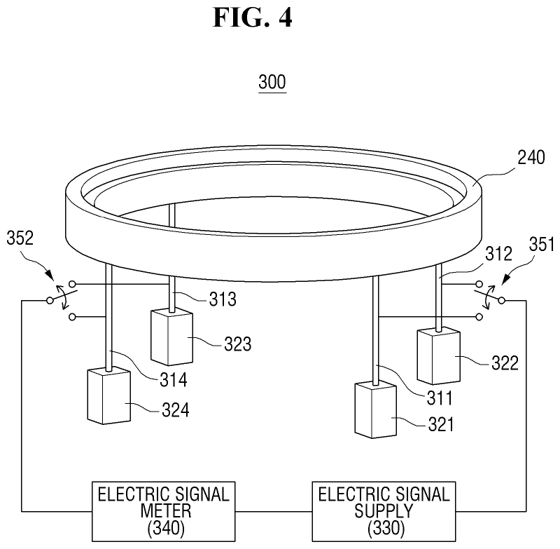

FIG. 4 is a conceptual view illustrating a focus ring height adjusting device according to another embodiment of the present disclosure. The following descriptions will be made with reference to FIG. 4.

Four lift pins 311, 312, 313, and 314, that is, a first lift pin 311, a second lift pin 312, a third lift pin 313, and a fourth lift pin 314, are respectively connected to four lift pin controllers 321, 322, 323, and 324, that is, a first lift pin controller 321, a second lift pin controller 322, a third lift pin controller 323, and a fourth lift pin controller 324.

A first switching element 351 is formed on a wire connecting an electric signal supply 330 to the first lift pin 311 or the second lift pin 312. The electric signal supply 330 may be connected to any one of the first lift pin 311 and the second lift pin 312 according to control of the first switching element 351.

A second switching element 352 is formed on a wire connecting the electric signal meter 340 to the third lift pin 313 or the fourth lift pin 314. The electric signal meter 340 may be electrically connected to any one of the third lift pin 313 and the fourth lift pin 314 according to control of the second switching element 352.

A focus ring height adjusting device 300 in FIG. 4 may select and use two lift pins from among four lift pins 311, 312, 313, and 314 to adjust a height of a focus ring 240. As an example, in a case in which the first lift pin 311 and the fourth lift pin 314 are used, the first switching element 351 and the second switching element 352 are used to respectively electrically connect the electric signal supply 330 and the electric signal meter 340 to the first lift pin 311 and the fourth lift pin 314, and the height of the focus ring 240 may be adjusted.

However, the present embodiment is not limited thereto. The switching elements may also not be provided, and the electric signal supply 330 and the electric signal meter 340 may also be provided to correspond to the number of the pairs of lift pins.

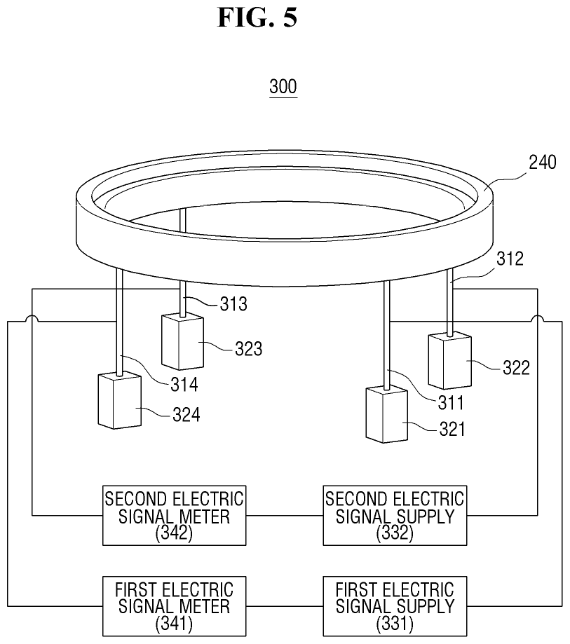

As an example, in a case in which the lift pins 311, 312, 313, and 314 are provided, as illustrated in FIG. 5, the first electric signal supply 331 and the first electric signal meter 341 may be respectively electrically connected to the first lift pin 311 and the fourth lift pin 314, and the second electric signal supply 332 and the second electric signal meter 342 may be respectively electrically connected to the second lift pin 312 and the third lift pin 313. FIG. 5 is a conceptual view illustrating a focus ring height adjusting device according to still another embodiment of the present disclosure.

Next, a method of compensating for a height of the focus ring using the focus ring height adjusting device 300 will be described.

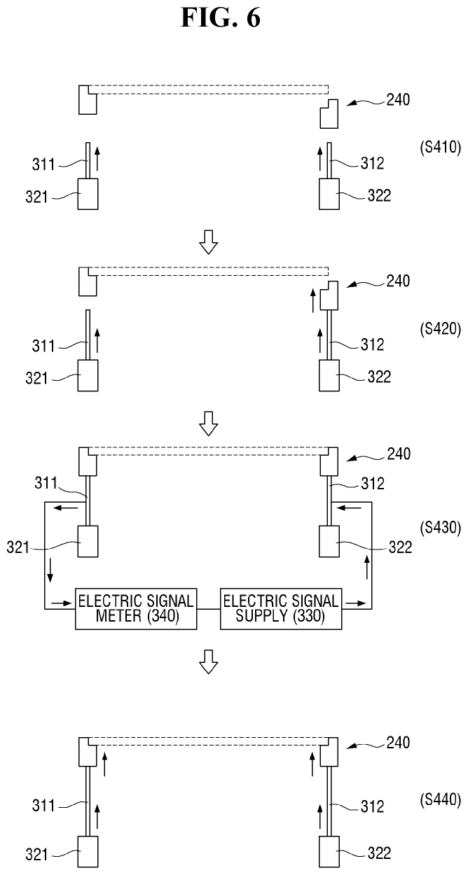

FIG. 6 is a flow view illustrating a method of compensating for a height of a focus ring using a focus ring height adjusting device according to one embodiment of the present disclosure. The following descriptions will be made with reference to FIG. 6.

First, a first lift pin controller 321 and a second lift pin controller 322 are used to move a first lift pin 311 and a second lift pin 312, which are collinear with each other, upward at the same speed (S410). Here, the first lift pin 311 and the second lift pin 312 may be moved upward simultaneously, but the present embodiment is not limited thereto.

When a focus ring 240 is inclined in one direction, the first lift pin 311 and the second lift pin 312 do not simultaneously come into contact with the focus ring 240, and any one of the first lift pin 311 and the second lift pin 312 may come into contact with the focus ring 240 first. Hereinafter, an example of a case in which the second lift pin 312 comes into contact with the focus ring 240 first will be described.

Since the first lift pin 311 does not come into contact with the focus ring 240 even when the second lift pin 312 comes into contact with the focus ring 240, a closed circuit in which the second lift pin 312, the focus ring 240, the first lift pin 311, an electric signal meter 340, and an electric signal supply 330 are sequentially connected is not formed. Accordingly, a current does not flow through the electric signal meter 340 in this case, and thus, the first lift pin 311 and the second lift pin 312 are continuously moved upward at the same speed (S420).

Then, when the first lift pin 311 comes into contact with the focus ring 240 after the second lift pin 312 comes into contact with the focus ring 240, the closed circuit is formed, and thus the electric signal meter 340 may measure a current. In addition, the focus ring 240 is not inclined anymore in one direction in this case, and a horizontal state thereof is maintained on the ESC 230 (S430).

In the present embodiment, a height of the focus ring 240 is adjusted using stepping motors installed on the lift pins 311 and 312, and in this case, it is important to check a time point at which the lift pins 311 and 312 come into contact with the focus ring 240 for horizontal alignment of the focus ring 240.

When the focus ring 240 and the lift pins 311 and 312 are formed of conductive materials, electric signals are transmitted to the lift pins 311 and 312, and thus the closed circuit is formed at a moment at which the lift pins 311 and 312 come into contact with the focus ring 240, and the formed closed circuit may be detected to check a time point at which the focus ring 240 comes into contact with the lift pins 311 and 312.

Then, pulses of the stepping motors forming the first lift pin controller 321 and the second lift pin controller 322 may be adjusted to control an increasing height of the first lift pin 311 and an increasing height of the second lift pin 312 (S440).

As described above, a method of horizontally aligning the focus ring using the electric signals is described with reference to FIGS. 1 to 6. A technology for transferring the focus ring is required to improve productivity, and particularly, a technology for moving the focus ring becomes important as a technology corresponding to ring etching. When the focus ring moves, the horizontal alignment is very important, and the present disclosure has a characteristic that the electric signals are transmitted to the lift pins to check horizontal alignment of the focus ring.

Although the embodiments of the present disclosure have been described with reference to the accompanying drawings, it will be understood by those skilled in the art that the disclosure may be performed in other concrete forms without changing the technological scope and essential features. Therefore, the above-described embodiments should be considered only as examples in all aspects and not for purposes of limitation.

What is claimed is:

1. A focus ring height adjusting device comprising:
a focus ring;
a first lift pin configured to move upward at one side of the focus ring height adjusting device to come into contact with the focus ring; and
a second lift pin configured to move upward at the other side of the focus ring height adjusting device to come into contact with the focus ring,
wherein the first lift pin and the second lift pin move upward until both of the first lift pin and the second lift pin come into contact with the focus ring to compensate for an inclination of the focus ring.

2. The focus ring height adjusting device of claim 1, wherein the focus ring, the first lift pin, and the second lift pin are formed of conductive materials.

3. The focus ring height adjusting device of claim 2, wherein the conductive material includes any one of silicon carbide (SiC) and titanium dioxide (TiO₂).

4. The focus ring height adjusting device of claim 1, wherein:
the first lift pin and the second lift pin are electrically connected; and
whether both of the first lift pin and the second lift pin come into contact with the focus ring is determined on the basis of whether a closed circuit is formed between the focus ring, the first lift pin, and the second lift pin.

5. The focus ring height adjusting device of claim 4, further comprising:
an electric signal supply provided on a wire electrically connecting the first lift pin to the second lift pin and configured to transmit an electric signal to the first lift pin and the second lift pin; and
an electric signal meter provided on the wire and configured to determine whether the electric signal is flowing,
wherein the electric signal supply and the electric signal meter are used to determine whether the closed circuit is formed.

6. The focus ring height adjusting device of claim 4, wherein the first lift pin and the second lift pin continuously move upward at the same speed until it is determined that the closed circuit is formed.

7. The focus ring height adjusting device of claim 1, further comprising:
a first lift pin controller configured to vertically move the first lift pin; and
a second lift pin controller configured to vertically move the second lift pin,
wherein the first lift pin controller and the second lift pin controller include stepping motors, and pulses of the stepping motors are adjusted to control moving distances of the first lift pin and the second lift pin.

8. A wafer etching apparatus comprising:
a housing;
a shower head installed in the housing and serving as an upper electrode;
a susceptor installed in the housing and serving as a lower electrode;
an electro-static chuck (ESC) which is installed on the susceptor and on which a wafer is seated; and
a focus ring height adjusting device including a focus ring formed on the susceptor to surround the wafer, a first lift pin configured to move upward at one side of the focus ring height adjusting device to come into contact with the focus ring, and a second lift pin configured to move upward at the other side of the focus ring height adjusting device to come into contact with the focus ring, wherein the focus ring height adjusting device moves the first lift pin and the second lift pin upward until both of the first lift pin and the second lift pin come into contact with the focus ring to compensate for an inclination of the focus ring.

9. The wafer etching apparatus of claim 8, wherein the focus ring, the first lift pin, and the second lift pin are formed of conductive materials.

10. The wafer etching apparatus of claim 8, wherein:
the first lift pin and the second lift pin are electrically connected; and
whether both of the first lift pin and the second lift pin come into contact with the focus ring is determined on the basis of whether a closed circuit is formed between the focus ring, the first lift pin, and the second lift pin.
